(19) United States
(12) Patent Application Publication
(10) Pub. No.: US 2022/0065935 A1
(43) Pub. Date: Mar. 3, 2022

(54) PREDICTING FUTURE BATTERY SAFETY THREAT EVENTS WITH CAUSAL MODELS

(71) Applicant: Hewlett-Packard Development Company, L.P., Spring, TX (US)

(72) Inventors: Augusto Queiroz de Macedo, Porto Alegre (BR); Arthur Sena Lins Caldas, Porto Alegre (BR); Giovani Barbosa, Porto Alegre (BR); Paul Monthaler, Porto Alegre (BR); Eanes Torres Pereira, Porto Alegre (BR)

(73) Assignee: Hewlett-Packard Development Company, L.P., Spring, TX (US)

(21) Appl. No.: 17/418,192

(22) PCT Filed: May 8, 2019
(86) PCT No.: PCT/US2019/031315

§ 371 Date: Jun. 24, 2021

(51) Int. Cl. G01R 31/367; G06F 1/28; G06N 7/00

(52) U.S. Cl. CPC G01R 31/367; G06N 7/005; G06F 1/28

(57) ABSTRACT

In various examples, a plurality of data points indicative of a history of a battery may be obtained and analyzed based on a causal model to predict a future safety threat event of the battery. The causal model may include a plurality of nodes linked by edges. Each node may represent an event and each edge may represent an observed cause-effect relationship between an event represented by one node of the causal model and another event represented by another node of the causal model. One of the nodes of the causal model may represent the future safety threat event of the battery.

### BACKGROUND

Batteries may fail in various ways for a variety of reasons. For example, some types of batteries, such as lithium-ion batteries, have been known to fail in ways that present safety threats, such as by becoming unstable, leaking fluids, catching fire, or even exploding. These types of failures may be caused by violations or breaches that are electrical, thermal, and/or mechanical in nature.

For example, thermal runaway, one of the worst types of battery failure, can be caused by exothermic materials decomposition, gas evolution, and/or electrolyte combustion. In some cases thermal runaway may begin with an uncontrolled release of heat from one battery cell that propagates to neighbor cells. This may result in a gas overpressure that causes venting, sometimes with flames. Various external and internal factors may contribute to thermal runaway, such as external shock or mechanical abuse, extreme external temperatures, fuse failure, short circuit, charge/discharge errors, etc.

### BRIEF DESCRIPTION OF THE DRAWINGS

Features of the present disclosure are illustrated by way of example and not limited in the following figure(s), in which like numerals indicate like elements.

FIG. 1 depicts an example process flow that demonstrates how various aspects of the present disclosure relate to each other.

FIG. 2 demonstrates an example of how data may be exchanged between various entities in order to practice selected aspects of the present disclosure.

FIG. 3 demonstrates an example of a causal model for predicting a risk posed to/by a battery.

FIG. 4 demonstrates another example of a causal model for predicting a risk posed to/by a battery.

FIG. 5 depicts an example method for practicing selected aspects of the present disclosure.

FIG. 6 shows a schematic representation of a computing device, according to an example of the present disclosure.

### DETAILED DESCRIPTION

For simplicity and illustrative purposes, the present disclosure is described by referring mainly to an example thereof. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Additionally, it should be understood that the elements depicted in the accompanying figures may include additional components and that some of the components described in those figures may be removed and/or modified without departing from scopes of the elements disclosed herein. It should also be understood that the elements depicted in the figures may not be drawn to scale and thus, the elements may have different sizes and/or configurations other than as shown in the figures.

Various examples described herein relate to generating and using causal models along with various data points associated with batteries' histories to predict future states of the batteries, such as safety threat events that are known to occur with lithium-ion batteries. In various examples, data indicative of a history of a battery may be obtained from multiple sources, including but not limited to a battery developer, battery manufacturer, an entity that installs batteries into computing devices (e.g., laptops, smart phones, tablet computers, hybrid computers, smart watches, head-mounted displays, etc.), and/or a computing device in which the battery is installed. These data may then be used in conjunction with a causal model to predict a future state of the battery, such as predicting if/when (or under what future circumstances) the battery may rupture.

Causal models may take various forms, such as directed Bayesian graphs that include nodes and edges. Each node may represent an event (e.g., data point) associated with a life of a battery and each edge may represent an observed cause-effect relationship between an event represented by one node of the causal model and another event represented by another node of the causal model. In some examples, each node or edge may include a function that receives, as input, data from upstream node(s), and outputs a value that may or may not be propagated to downstream node(s). These functions may take various forms, such as heuristics, probabilities/weighted contributions, statistical models such as trained machine learning models, etc.

In various examples, causal models may be assembled by various entities associated with the lifetime of a battery, such as the battery's developer, manufacturer, a manufacturer of a computing device in which the battery is installed, etc. Once assembled, the causal models may be implemented at a computing device in which the battery being monitored is installed, on the “cloud” using data uploaded from a computing device in which the battery is installed, or any combination in between. The causal models may also be updated periodically when it is determined that ground truth data does not comport with predictions made using the causal models.

The causal models may be generated based on expert knowledge, empirical data, and/or experimentation performed by/at the various entities. Consequently, the causal models encode observed cause-effect relationships between various events and/or data points associated with batteries. This contrasts with statistical models, which generally capture correlation amongst various data points, but not necessarily causation. However, statistical models may still be employed at various points in a causal model, e.g., as one of the aforementioned functions that, for instance, reinforces a node of the causal model that predicts a future battery state.

For example, it may be determined experimentally that a plurality of factors contribute to a particular future battery event or state (e.g., increased temperature). In some examples, each factor's contribution to the future battery event or state may be captured in a trained machine learning model. Statistical models may additionally or alternatively be used to for other purposes. For example, over time a trained statistical model may reveal a correlation between two or more factors that were heretofore considered causally independent. In some such examples, the causal model may be updated to change a relationship between two nodes of the causal model between causal independence and causal dependence.

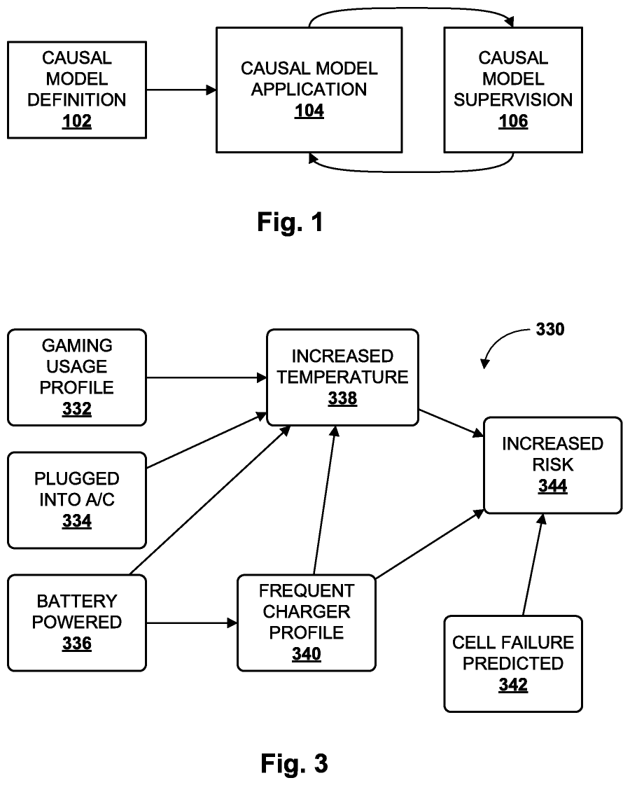

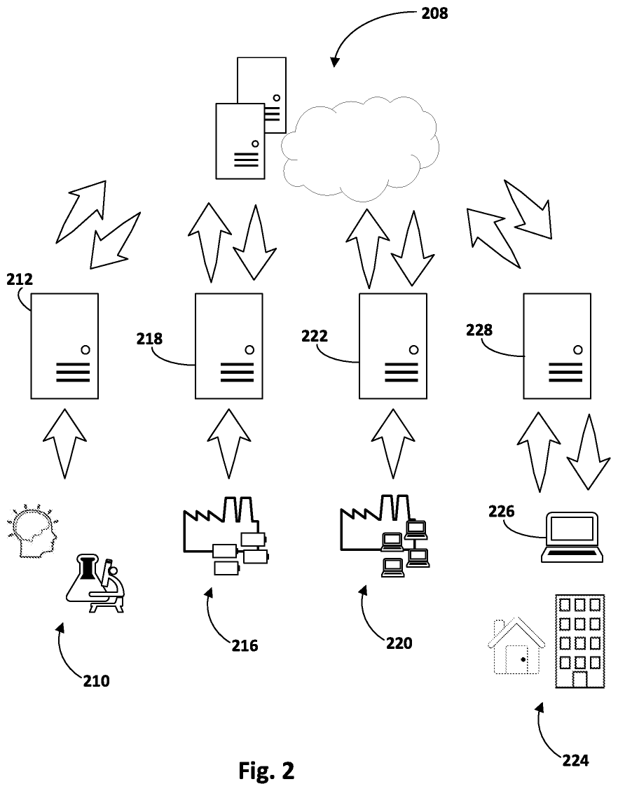

Referring now to FIG. 1, during a phase of causal model definition 102, various entities associated with the lifetime of batteries may assemble causal models that can be used to predict future states of batteries, including safety threat events such as thermal runaway. As noted previously, these entities may include, but are not limited to, battery developers (e.g., research and development), battery manufacturers, manufacturers of computing devices in which batteries are installed, etc. In some examples, causal sub-models may be generated by each entity, and then assembled with causal sub-models generated by other entities to yield a full causal model. FIG. 2 schematically depicts one example of how various entities may interact to generate causal models.

The causal models generated during causal model definition 102 may take various forms, such as path diagrams, directed acrylic graphs, causal Bayesian networks, etc. Causal models may be stored in computer memory as various types of data structures in various formats, including but not limited to extensible markup language (“XML”) files, JavaScript Object Notation (“JSON”) files, etc. Causal models may be packaged or embodied with batteries in various ways, such as in computer-executable instructions forming part of a device driver associated with a battery, a battery management service (“BMS”) that runs on a computer in which a battery is installed, etc.

Causal models may utilize various types of mathematical constructs and concepts, including but not limited to linear equations with fixed parameters as well as non-parametric analysis. In some examples, a causal model may include a plurality of nodes linked by edges. Each node may represent an event and each edge may represent an observed cause-effect relationship between an event represented by one node of the causal model and another event represented by another node of the causal model. In various examples, some nodes may represent future states of the battery, such as a future safety threat event of the battery.

In some examples, the causal models may be defined by the various entities as a causal model of events that potentially lead to safety threat events associated with batteries. Each entity is able to provide its own expertise and/or technical discipline regarding batteries when generating its portion of an overall causal model. For example, during battery development, also referred to as research and development, batteries and battery prototypes under development undergo a range of tests and experiments. These tests and experiments may be selected based on a body of knowledge accumulated by the entity over time, including previous mistakes and risks made or observed by the entity. The knowledge gained from these tests and experiments may be incorporated into a causal sub-model associated with battery development.

Battery manufacturers may learn various things from their experiences manufacturing batteries, e.g., for commercial release, and may incorporate these teachings into their own causal sub-model. For example, battery manufacturers may deal with factors such as mass storage of battery inventories, storage of constituent battery components, chemical characteristics, handling, ambient temperature exposure, and many other factors found in manufacturing facilities such as factories. These factors, and how they dealt with, may have impacts on the battery's lifetime and/or a risk of the battery suffering a safety threat event. Accordingly, the battery manufacturer may incorporate their knowledge and/or observations regarding these various factors into their own causal sub-model.

A computer manufacturer may install batteries into computing devices before selling the computing devices to customers. Batteries may be incorporated into various types of devices, including computing devices such as laptops, tablet computers, smart phones, media players, portable gaming devices, portable headphones, head-mounted displays, smart watches, smart glasses, various smart appliances, and so forth.

A computer manufacturer may deal with some of the same challenges as a battery manufacturer, such as mass storage of battery inventories, handling, ambient temperature exposure, and so forth. Additionally, the computer manufacturer may deal with other factors associated with computer manufacturing and the role of batteries in that process, including but not limited to time to assembly, battery age, movements, tests such as stress tests, and so forth. As with the other entities, these factors associated with computer manufacturing, and how they dealt with, may have impacts on the battery's lifetime and/or a risk of the battery suffering a safety threat event. Accordingly, the computer manufacturer may incorporate their knowledge and/or observations regarding these various factors into their own causal sub-model.

Once a battery is installed into a computing device and deployed, there are numerous events and/or situations in which the battery may be subjected to various stresses and/or pressures. These may have impacts on the battery's lifetime and/or a risk of the battery suffering a safety threat event. For example, battery usage, or how a battery is used after its release as part of a commercial product, may have affect the batteries lifetime and/or risk of failure in various ways. In some examples, marketing and/or customer experience experts, suppliers, and/or engineers may act together to build causal models that show risky usages whenever the computer is moved around, sitting stationary, how much the battery is allowed to discharge before being charged (discharge depth), and so forth.

In addition, during usage, various battery tests may be run, e.g., by a BMS implemented on a computing device in which a battery is installed or on a server forming part of a cloud infrastructure. These battery tests may test various conditions of battery usages, such as how much time the computer is used while plugged into a power source (during which the battery may be charged) versus how much time the computer is operating using battery power.

In some examples, statistical models such as machine learning models may be trained and deployed, e.g., between cause and effect nodes, to predict future states of a battery given various collected data. Put another way, the statistical model may be a function between two nodes (cause-effect) of the causal model, which allows the function between cause and effect to have any level of complexity. As one non-limiting example, a statistical model trained to predict a battery cell failure may be related to a lower safety risk, while another statistical model that predicts a temperature rise may indicate a greater safety risk.

In some examples, entities that store batteries for various lengths of time, such as retailers, enterprise information technology departments, or any of the other entities mentioned previously, may also contribute to causal model generation. Batteries' lifetimes and/or risks of failure may be impacted by factors such as temperatures and/or humidity of environments in which the batteries are stored, whether the batteries were stored by themselves or installed in computing devices, whether the batteries were stored properly or simply placed on a shelf and allowed to gather dust, etc.

Referring back to FIG. 1, once causal models are defined by the various entities during the phase of causal model definition 102, they may be applied to data as part of a phase of causal model application 104. For example, a plurality of data points indicative of a history of a battery may be obtained from various entities, such as the entities mentioned previously. The plurality of data points may be analyzed based on a particular causal model to predict a future safety threat event of the battery. The particular causal model may be selected from a database (not depicted) of causal models, for instance, based on the selected causal model being associated with the particular type or model of battery under consideration.

During and after the phase of causal model application 104, a phase of causal model supervision 106 may take place. Causal models defined during causal model definition 102 and applied during causal model application 104 may be supervised and/or tested, e.g., to ensure they remain accurate given new ground truth data that continues to be generated in relation to batteries. When it is determined that various assumptions or inferences, or cause-effect relationships, are in fact untrue or are different than defined in the causal models, the causal models may be updated. These changes in turn may inform entities that created the causal models of potential causes of battery failure, as well as trigger remedial action if possible.

As an example, suppose some time has passed (e.g., months, years) since a particular type of battery has been deployed across multiple different types of computing devices. New data generated by or in relation to these batteries during this time may reveal additional causes and effects that may not have been evident when the batteries were released initially. For example, batteries installed in a first type of computing device may be failing at greater rates than the same type of battery installed in a second type of computing device.

A causal model associated with the battery type may be updated to account for this. For example, the causal model may be updated so that the first type of computing device is represented as causal node that exerts a relatively large influence on an effect node associated with failure of that type of battery. The second type of computing device may be represented as another causal node that exerts a lesser amount of influence on the effect node. In some examples, the edge between the node representing the first computing device and the effect node may be weighted more heavily than the edge between the node representing the second computing device and the effect node.

FIG. 2 demonstrates an example of how data may be exchanged between various entities in order to practice selected aspects of the present disclosure. In this example, each entity has its own server computer that manages the exchange of data with a cloud infrastructure 208 (which may be considered “remote” from the respective servers). This may provide benefits such as diminished impact of the battery data exchange on local area network bandwidths, better security/management, easier maintenance, etc. However, this is not meant to be limiting. In some examples, any of the entities may not have its own server computer to manage data exchange with cloud infrastructure 208, and instead may include individual computing device(s) or even individual sensor(s) (e.g., thermometers, hygrometers) that each exchanges data with cloud infrastructure 208 on an individual basis.

Cloud infrastructure 208 may be maintained and/or controlled by any one of the entities described herein that is interested in being able to predict future battery states, e.g., for presentation to end users, such as a computer manufacturer 220. In some examples, cloud infrastructure 208 may facilitate generation, storage, and/or maintenance of causal models generated and applied using techniques described herein. When it is determined that a causal model is in need of an update, that may be handled at/by cloud infrastructure 208.

A battery developer 210 that researches and develops a new battery may include a server 212 that captures data generated during experimentation and testing of batteries under development, e.g., for transmission to cloud infrastructure 208. A battery manufacturer 216 that manufactures batteries once their development is complete likewise may include a server 218 that captures data generated during manufacture of batteries.

A computer manufacturer 220 that installs batteries manufactured by battery manufacturer 216 into computing devices such as those battery-powered devices described previously may include a server 222. Computer manufacturer server 222 may capture data generated during manufacture of computing devices, particularly data associated with batteries that are installed in the computing devices.

End users 224, whether in the commercial and/or consumer domains, may operate the computing devices 226 manufactured by computer manufacturer 220. In some examples, including that depicted in FIG. 2, a plurality of computing devices 226 operated by end users 224 may transmit data to an end users server 228. End users server 228 may capture data generated during use of computing devices in which batteries are installed, particularly data that impacts battery lifetimes and/or failure risks. For instance, in some examples, a BMS running on each individual computing device 226 may capture various data relevant to battery operation, such as temperature, humidity, how much a computing device is operated using battery power versus how much the computing device is operated using AC mains, how much the computing device's resources such as memory and processor cycles are pushed to their extremes (which may require more power and/or raise temperatures), etc.

Any of servers 212, 218, 222, 228 may download data from cloud infrastructure 208, including but not limited to updated causal models. Any of servers 212, 218, 222, 228 may also upload event logs to cloud infrastructure 208. These event logs may evidence matches, or mismatches, between observed ground truth data and cause-effect dependencies of a causal model. In some examples, any of servers 212, 218, 222, 228 may provide event logs having greater detail when mismatches between ground truth and causal model predictions are observed, e.g., because mismatches have more impact on causal models than matches.

As an example, suppose a causal model assumes causal independence between a way a computer moves around an environment and a temperature increase experienced by the battery. Suppose further that ground truth data generated by any of entities 210, 216, 220, 224 begins to evidence a correlation between these factors. For example, a measure such as the Pearson product-moment correlation coefficient may be determined between the factors. This mismatch between ground truth observation and causal model prediction may trigger an upload of event log(s) to cloud infrastructure 208. These data may then be parsed and studied, and the causal model may be updated and then transmitted back down through servers 212, 218, 222, 228. In some examples servers 212, 218, 222, 228 may then provide the updated causal model to BMS's that are implemented on computing devices in which batteries are installed. More generally, causal models may, in some examples, be updated by employing “causal search methods,” also known as “structural learning methods,” to search for new causes to various effects.

In some examples, cloud infrastructure 208 may generate and maintain a “digital twin” of a real-world battery installed in a deployed computing device. In some such examples, various data may be provided from servers 212, 218, 222, 228 to cloud infrastructure 208 that includes observations of the battery and its environment. Numerous different types of sensors may be deployed to generate data relevant to a battery. This data may be provided to servers 212, 218, 222, 228, which in turn may relay this data to cloud infrastructure 208.

For example, many batteries include internal chemical and/or electrical sensors that generate data related to the internal usage/health of the batteries. As another example, some batteries may be equipped with wireless transmitters such as radio frequency identification (“RFID”) transmitters. Signals raised by such a transmitter may be used, for instance, to trace a battery's location over time.

As another example, various factors external to batteries, such as ambient temperatures, humidity, vibration, etc., may be measured by various types of sensors external to batteries. As another example, in some cases, vision sensors such as infrared cameras may be used to measure heat around a battery.

In some examples, data generated by sensor(s) and used to predict future states of a battery may be provided, along with the predictions, to cloud infrastructure 208. For example, data used to predict battery failure, or to predict future temperature increases that may accelerate battery failure, may be provided to cloud infrastructure 208 along with the predictions. Data that may predict future temperature increases may include, for instance, current and past usage data.

FIG. 3 depicts on example of a portion 330 of a causal model that predicts an increased risk of a safety threat event based on data generated during computer usage. A first node 332 represents data associated with a gaming usage profile. Computer gaming, particularly when the game is graphics-intensive, may utilize considerable computing resources such as central processing unit (“CPU”) processor cycles, graphics processing unit (“GPU”) processor cycles (which may in some cases consume more power than CPU cycles), and memory. This increased stress may raise the temperature of various components of a computing device, such as the CPU and/or GPU.

Consequently, an increased temperature, represented by node 338, may be experienced by a battery installed in the computing device. In some examples, statistics associated with usage of the computing device for gaming, i.e., gaming usage profile node 332, such as time playing games, the amount of resources utilized to play those games, etc., may be gathered and provided, as input from node 332 to node 338. Put another way, the edge between nodes 332 and 338 reflects the cause-effect relationship between the gaming profile and the consequent increase(s) in temperature experienced by the battery. In some examples, the edge may be weighted to reflect the relative influence of gaming on temperature increases experienced by the battery compared to other factors (e.g., nodes 332-336, 340, described below).

Other factors or causes that contribute to the effect of the battery experiencing increased temperatures 338 include usage of the computing device in which the battery is installed that is powered by AC mains power versus usage of the computing device powered by the battery itself. These two events/causes are represented, respectively, by nodes 334 and 336. When the computing device is operated while plugged into AC mains, the battery may be constantly charged, which can raise its temperature to some degree. Similarly, when the computing device is operated on battery power, its temperature may be raised to some other degree.

In addition, if the computing device is operated relatively frequently on battery power alone, that may require frequent recharging, e.g., plugging the computer while it's not in use. Frequently recharging a battery may have its own unique impact on increased temperatures experienced by the battery. Accordingly, data pertaining to this frequent recharging may be captured by a frequent charger profile node 340, and may act as another cause that leads to the effect of increased temperature node 338. In various examples, the respective influences of nodes 334, 336, and 340, together with node 332, may be taken into account by the increased temperature node 338.

As shown in FIG. 3, an effect of increased risk of a safety threat event is represented by node 344. Node 344 takes into account, e.g., as an input, the increased temperature event(s) captured by node 338. Node 344 also takes into account, e.g., as additional inputs, the frequent charger profile node 340 and a cell failure prediction node 342.

Cell failure prediction model 342 represents a prediction—which may be based on data/nodes not pictured in FIG. 3—that a cell of the battery is going to fail. For example, data generated by battery sensor(s) that measure chemical and/or electrical properties may generate sensor data. This sensor data may be applied to a function such as a statistical model, which may be trained to predict cell failure based on such sensor data. When the statistical model predicts cell failure, that prediction itself may be deemed a cause because it simulates a particular future state of the battery. In some such examples, the causal model may be evaluated from that future point in time, taking into account the actual cause-effect results, e.g., an increased risk 344 of a safety threat event.

More generally, and as noted previously, each node of a causal model, such as those nodes depicted in FIG. 3, may correspond to a function that receives, as input, data from upstream node(s) and generates output that is then provide to downstream node(s). These functions may take various forms, such as heuristics, relative weightings of multiple input edges, trained statistical models, and so forth. Trained statistical models that may be employed as node functions may include, but are not limited to, various types of neural networks, support vector machines, regression models, hidden Markov models, and so forth.

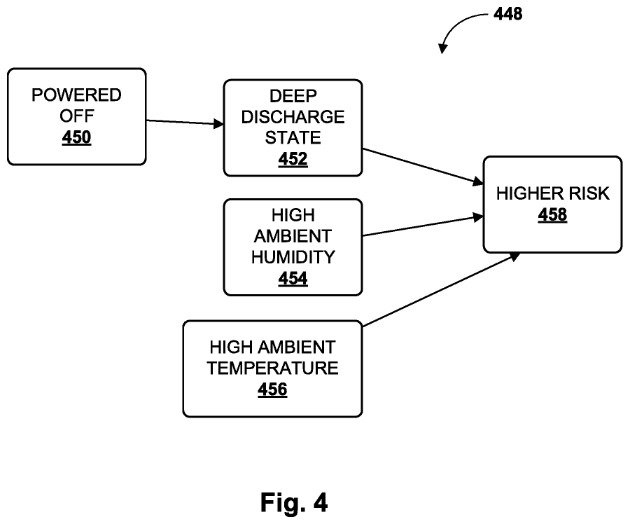

FIG. 4 depicts another example portion 448 of a causal model that predicts an increased risk of a safety thread event based on data generated while batteries are stored, e.g., at facilities of battery manufacturer 216, computer manufacturer 220, or even retailers of computing devices in which batteries are installed. Causal model portion 448 includes a “powered off” node 450 that corresponds to the battery not being used, whether it is installed in a computing device or not.

Being powered off causes the battery to experience the event of deep discharge 452, in which its cells are more completely drained of energy than they would be if used occasionally. Also shown in causal model portion 448 is a “high ambient humidity” event 454 that corresponds to humidity detected in a location in which the battery is stored, and a “high ambient temperature” event 456 that corresponds to a relatively high temperature experienced by the battery. In the example of FIG. 4, being exposed to both high humidity and temperatures may increase the likelihood of the battery transitioning to a higher risk 458 of safety threat event if it is used. In some cases, the longer the battery is exposed to the high humidity and temperatures, the greater the risk.

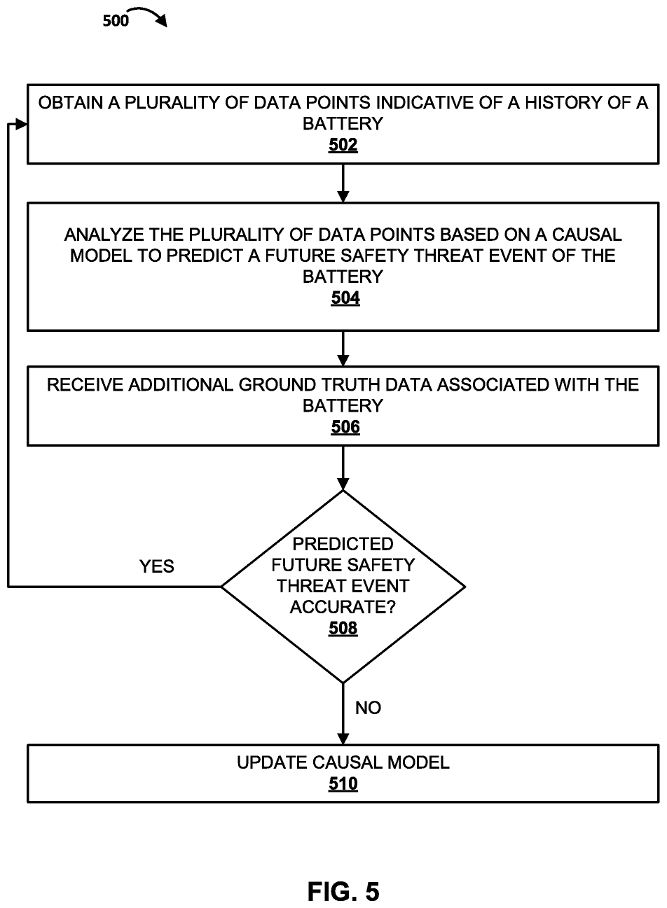

FIG. 5 illustrates a flowchart of an example method 500 for practicing selected aspects of the present disclosure. The operations of FIG. 5 may be performed by a processor, such as a processor of the various computing devices/systems described herein, which in some cases may implement the BMS described previously. For convenience, operations of method 500 will be described as being performed by a system configured with selected aspects of the present disclosure. Other implementations may include additional operations than those illustrated in FIG. 5, may perform operations (s) of FIG. 5 in a different order and/or in parallel, and/or may omit various operations of FIG. 5.

At block 502, the system may obtain a plurality of data points indicative of a history of a battery. These points may constitute ground truth data indicative of conditions experienced by the battery. These points may be obtained from various sources, such as sensor(s) integral with the battery, sensor(s) external to the battery, tracking devices such as RFID trackers, and so forth. These sources may be associated with various entities, such as those mentioned previously.

At block 504, the system may analyze the plurality of data points based on a causal model to predict a future safety threat event of the battery. In various examples, the causal model may include a plurality of nodes linked by edges. Each node may represent an event and each edge may represent an observed cause-effect relationship between an event represented by one node of the causal model and another event represented by another node of the causal model. One of the nodes may represent the future safety threat event of the battery. And as noted herein, individual node(s) of the causal model may correspond to functions, such as heuristics, weighted edges, or statistical models, which receive data from upstream node(s) as input, and provide output to downstream node(s).

In some examples, method 500 may continue at block 506, at which point additional ground truth data associated with the battery may be received. For example, as the battery is used as part of a computing device, the computing device's BMS may, e.g., as a system-as-a-service, continue to provide selected sensor data to cloud infrastructure 208.

At block 508, the system may determine whether the future safety threat event predicted at block 504 was accurate. For example, a battery failure may have been predicted at a particular time at block 504. However, subsequent ground truth data associated with the battery may reveal that the battery failed much earlier than predicted, e.g., weeks or months earlier. If the answer at block 508 is yes, then method 500 may proceed back to block 502. However, if the answer at block 508 is no, then method 500 may proceed to block 512. At block 512, the system may update the causal model to better reflect the reality shown in the ground truth data.

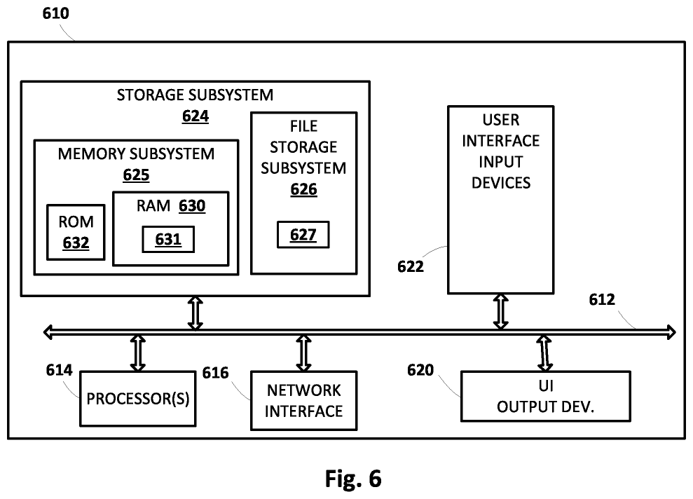

FIG. 6 is a block diagram of an example computer system 610, which in some examples may be representative of components found on a computing device configured with selected aspects of the present disclosure. Computer system 610 may include a processor 614 which communicates with a number of peripheral devices via bus subsystem 612. These peripheral devices may include a storage subsystem 626, including, for example, a memory subsystem 625 and a file storage subsystem 626, user interface output devices 620, user interface input devices 622, and a network interface subsystem 616. The input and output devices allow user interaction with computer system 610. Network interface subsystem 616 provides an interface to outside networks and is coupled to corresponding interface devices in other computer systems.

User interface input devices 622 may include input devices such as a keyboard, pointing devices such as a mouse, trackball, a touch interaction surface, a scanner, a touchscreen incorporated into the display, audio input devices such as voice recognition systems, microphones, vision sensor(s), and/or other types of input devices. In general, use of the term “input device” is intended to include all possible types of devices and ways to input information into computer system 610 or onto a communication network.

User interface output devices 620 may include a display subsystem, a printer, a fax machine, or non-visual displays such as audio output devices. The display subsystem may include a cathode ray tube (“CRT”), a flat-panel device such as a liquid crystal display (“LCD”), a projection device, or some other mechanism for creating a visible image. The display subsystem may also provide non-visual display such as via audio output devices. In general, use of the term “output device” is intended to include all possible types of devices and ways to output information from computer system 610 to the user or to another machine or computer system.

Storage subsystem 624 stores machine-readable instructions and data constructs that provide the functionality of some or all of the modules described herein. These machine-readable instruction modules are generally executed by processor 614 alone or in combination with other processors. Memory 625 used in the storage subsystem 624 may include a number of memories.

For example, a main random access memory (“RAM”) 630 may be used during program execution to store, among other things, instructions 631 for operating a BMS configured with selected aspects of the present disclosure as described herein. Memory 625 used in the storage subsystem 624 may also include a read-only memory (“ROM”) 632 in which fixed instructions are stored.

A file storage subsystem 626 may provide persistent or non-volatile storage for program and data files, including instructions 627 for operating a BMS configured with selected aspects of the present disclosure, and may include a hard disk drive, a floppy disk drive along with associated removable media, a CD-ROM drive, an optical drive, or removable media cartridges. The modules implementing the functionality of certain implementations may be stored by file storage subsystem 626 in the storage subsystem 626, or in other machines accessible by the processor(s) 614.

Bus subsystem 612 provides a mechanism for letting the various components and subsystems of computer system 610 communicate with each other as intended. Although bus subsystem 612 is shown schematically as a single bus, other implementations of the bus subsystem may use multiple busses.

Computer system 610 may be of varying types including a workstation, server, computing cluster, blade server, server farm, or any other data processing system or computing device. Due to the ever-changing nature of computers and networks, the description of computer system 610 depicted in FIG. 6 is intended as a specific example for purposes of illustrating some implementations. Many other configurations of computer system 610 are possible having more or fewer components than the computer system depicted in FIG. 6.

Although described specifically throughout the entirety of the instant disclosure, representative examples of the present disclosure have utility over a wide range of applications, and the above discussion is not intended and should not be construed to be limiting, but is offered as an illustrative discussion of aspects of the disclosure.

What has been described and illustrated herein is an example of the disclosure along with some of its variations. The terms, descriptions and figures used herein are set forth by way of illustration and are not meant as limitations. Many variations are possible within the scope of the disclosure, which is intended to be defined by the following claims—and their equivalents—in which all terms are meant in their broadest reasonable sense unless otherwise indicated.

What is claimed is:

1. A computer-implemented method comprising:
obtaining a plurality of data points indicative of a history of a battery; and
analyzing the plurality of data points based on a causal model to predict a future safety threat event of the battery;
wherein the causal model comprises a plurality of nodes linked by edges, each node representing an event and each edge representing an observed cause-effect relationship between an event represented by one node of the causal model and another event represented by another node of the causal model, wherein one of the plurality of nodes represents the future safety threat event of the battery.

2. The computer-implemented method of claim 1, wherein the obtaining and analyzing are performed by a computing device powered by the battery.

3. The computer-implemented method of claim 1, further comprising:
determining, based on ground truth data associated with the battery, that the predicted future safety threat event was inaccurate; and
updating the causal model based on the determining.

4. The computer-implemented method of claim 3, wherein the updating comprises changing a relationship between two nodes of the causal model between causal independence and causal dependence.

5. The computer-implemented method of claim 4, further comprising identifying a correlation between the two nodes of the causal model, wherein the updating is performed in response to the identifying.

6. The computer-implemented method of claim 1, wherein the plurality of data points are obtained from a plurality of different entities that have interacted with the battery during its history.

7. The computer-implemented method of claim 6, wherein the plurality of different entities include two of a developer of the battery, a manufacturer of the battery, a manufacturer of a computing device in which the battery is installed, or the computing device in which the battery is installed.

8. The computer-implemented method of claim 1, wherein a given node of the plurality of nodes is associated with a function that generates output based on input data received by the given node from an upstream node.

9. The computer-implemented method of claim 1, wherein the battery comprises a lithium-ion battery.

10. A personal computing device, comprising:
a battery;
a processor; and
memory storing a causal model and instructions that, in response to execution of the instructions by the processor, cause the processor to:
obtain a plurality of data points indicative of a history of the battery; and
use the plurality of data points as input for the causal model to generate a prediction of a future state of the battery;
wherein the causal model comprises a plurality of nodes linked by edges, each node representing an event and each edge representing an observed cause-effect relationship between an event represented by one node of the causal model and another event represented by another node of the causal model, wherein a given node of the plurality of nodes represents the future state of the battery.

11. The personal computing device of claim 10, wherein the memory further comprises instructions to:
compare the predicted future state of the battery with an observed state of the battery to determine that the prediction of the future state of the battery was inaccurate; and
update the causal model.

12. The personal computing device of claim 11, further comprising instructions to:
identify a correlation between two nodes of the causal model that are represented by the causal model as causally independent; and
change a relationship between the two nodes of the causal model to causal dependence.

13. The personal computing device of claim 11, wherein the update of the causal model comprises receipt, by the personal computing device from a remote computing device, of an updated causal model.

14. The personal computing device of claim 10, wherein the plurality of data points are obtained from a plurality of different entities that have interacted with the battery during its history, and the plurality of different entities include a developer of the battery, a manufacturer of the battery, a manufacturer of a computing device in which the battery is installed, or the computing device in which the battery is installed.

15. A non-transitory computer-readable medium comprising instructions that, in response to execution of the instructions by a processor, cause the processor to:
obtain a plurality of data points associated with a battery; and
apply the plurality of data points as input for a causal network to generate output, wherein the output predicts a future safety threat event of the battery;
wherein the causal network encodes a plurality of events occurring over a lifetime of the battery and cause-effect relationships between the plurality of events, wherein a given event of the plurality of events comprises the future safety threat event of the battery.
